(19) United States
(12) Patent Application Publication
(10) Pub. No.: US 2005/0275311 A1
(43) Pub. Date: Dec. 15, 2005

(54) Compliant device for nano-scale manufacturing

(75) Inventors: Byung-Jin Choi, Round Rock, TX (US); Sidlgata V. Sreenivasan, Austin, TX (US)

Correspondence Address: MOLECULAR IMPRINTS, INC.;KENNETH C. BROOKS, PO BOX 81536, AUSTIN, TX, 78708-1536, US

(73) Assignee: MOLECULAR IMPRINTS, INC., Austin, TX (US)

(21) Appl. No.: 10/858,179

(22) Filed: Jun. 1, 2004

(51) Int. Cl. H01L 41/04; H01L 41/06

(52) U.S. Cl. 310/323.05

(57) ABSTRACT

The present invention is directed to a compliant device comprising a support body, a floating body, and a plurality of flexure arms. Each of the plurality of transfer arms is connected between the support body and the floating body to transfer a load therebetween in parallel. To that end, the flexure arms having first and second sets of flexure joints. The first set of flexure joints facilitating rotational movement of said flexure arm about a first axis extending along a first direction. The second set of flexure joints arranged to facilitate rotational movement of the flexure arm about a second axis, extending along a second direction that is transverse to the first direction. The flexure joints are revolute joints.

### BACKGROUND OF THE INVENTION

The field of invention relates generally to remote center compliant devices. More particularly, the present invention is directed to a compliant device suited for use in imprint lithography to hold a template.

Compliant devices are devices that have elastic properties to compliantly float one body relative to another, while providing a desired number of degrees of freedom of movement therebetween. These properties permit, inter alia, the floating body to compensate out-of-tolerance spatial orientations with respect to a work surface. Active compliant devices use actuators to achieve a desired spatial orientation between bodies. “Passive” compliant devices are unpowered, i.e., with out active control. Being able to be kinematically constrained in any translational or rotational direction, a “passive” compliant device achieves proper spatial orientation between the floating body and a work piece through interconnecting linkages and passive elastic elements, e.g., springs. Actuation of the compliance function occurs upon contact of the floating body with the work surface. To that end, forces transferred between the floating body and a support body coupled thereto via linkages may be achieved serially or in parallel.

An exemplary compliant device is shown in U.S. Pat. No. 6,696,220 to Bailey et al. that discloses a remote passive compliant device for use in imprint lithography. The remote passive compliant device facilitates a transfer of forces between the floating body and a support body coupled thereto serially, through a plurality of linkages. The linkages are coupled between the floating body and the support by via flexure joints. With this configuration, proper spatial orientation between an imprint lithography template and imprinting material of a work surface may be achieved.

Thus, a need exists for providing improved compliant devices for use in imprint lithography processes.

### SUMMARY OF THE INVENTION

The present invention is directed to a compliant device comprising a support body, a floating body, and a plurality of flexure arms. Each of the plurality of transfer arms is connected between the support body and the floating body to transfer a load therebetween in parallel. To that end, the flexure arms having first and second sets of flexure joints. The first set of flexure joints facilitate rotational movement of the flexure arm about a first axis extending along a first direction. The second set of flexure joints arranged to facilitate rotational movement of the flexure arm about a second axis, extending along a second direction that is transverse to the first direction. The flexure joints are revolute joints. Thus, the movement of the flexure arms is constrained to rotational movement about two transversely orientated axes. In one embodiment the compliant device is a passive compliant device. In an alternate embodiment, the compliant device is an active compliant device. These and other embodiments are discussed more fully below.

### SUMMARY OF THE INVENTION

The present invention is directed towards a method and system of controlling movement of a body coupled to an actuation system that features translating movement of the body in a plane extending by imparting angular motion in the actuation system with respect to two spaced-apart axes. Specifically, rotational motion is generated in two spaced-apart planes, one of which extending parallel to the plane in which the body translates. This facilitates proper orientation of body with respect to a surface spaced-apart therefrom. These and other embodiments are discussed more fully below.

### BRIEF DESCRIPTION OF THE DRAWINGS.

FIG. 1 is an exploded perspective view of an orientation stage showing a template chuck and a template in accordance with the present invention;

FIG. 2 is perspective view of the orientation stage shown in FIG. 1;

FIG. 3 is an exploded perspective view of a passive compliant device included in the orientation stage shown in FIG. 1 along with the template holder and the template in accordance with a first embodiment of the present invention;

FIG. 4 is a detailed perspective view of the passive compliant device shown in FIG. 3;

FIG. 5 is a side view of the passive compliant, device shown in FIG. 4, showing detail of flexure joints included therewith;

FIG. 6 is a side view of the passive compliant device shown in FIG. 4;

FIG. 7 is a side view of the compliant device, shown in FIG. 6, rotated 90 degrees;

FIG. 8 is a side view of the compliant device, shown in FIG. 6, rotated 180 degrees;

FIG. 9 is a side view of the compliant device, shown in FIG. 6, rotated 270 degrees; and

FIG. 10 is a perspective view of a compliant device in accordance with an alternate embodiment of the present invention;

FIG. 11 is a simplified elevation view of a the template, shown in FIG. 1, in superimposition with a substrate showing misalignment along one direction;

FIG. 12 is a top down view of the template and substrate, shown in FIG. 11, showing misalignment along two transverse direction;

FIG. 13. is a top down view of the template and substrate, shown in FIG. 11, showing angular misalignment;

FIG. 14 is a simplified elevation view of the template, shown in FIG. 1, in superimposition with a substrate showing angular misalignment;

FIG. 15 is a simplified elevation view showing desired alignment between the template and substrate shown in FIGS. 11, 12, 13 and 14;

FIG. 16 is a detailed view of one embodiment of the template shown in FIGS. 1, 3, 11, 12, 13, 14 and 15 in superimposition with a substrate; and

FIG. 17 is a detailed view of the template shown in FIG. 16 showing a desired spatial arrangement with respect to the substrate.

### DETAILED DESCRIPTION OF THE INVENTION

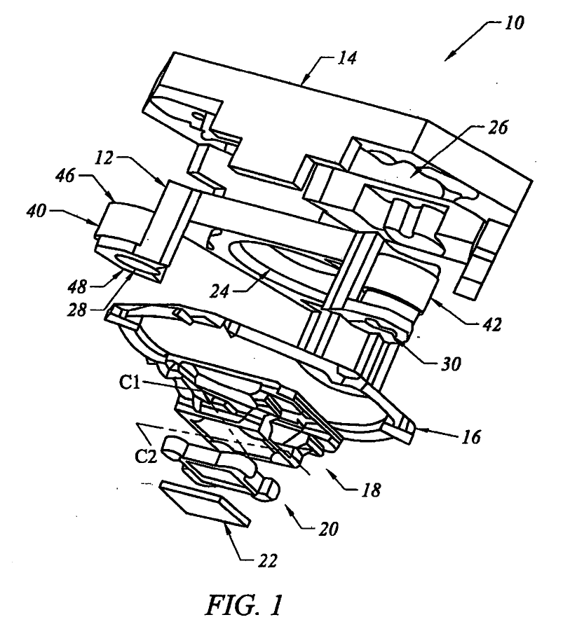

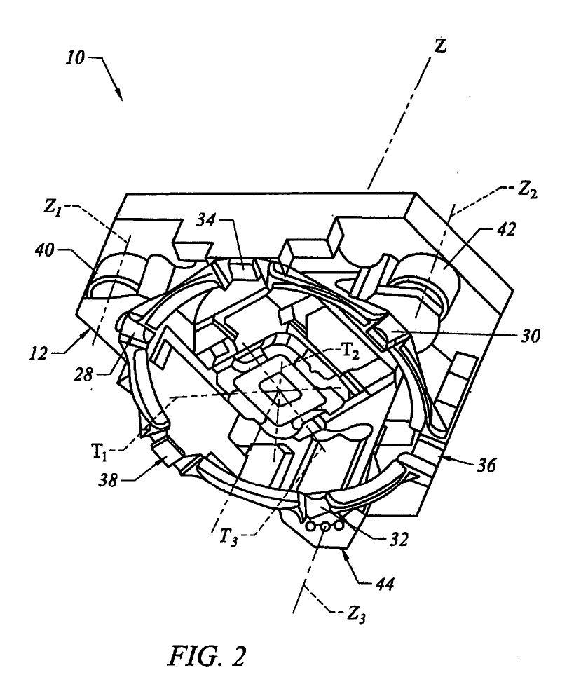

Referring to FIG. 1, an orientation stage 10 is shown having an inner frame 12 disposed proximate to an outer frame 14, a flexure ring 16 and a compliant device 18. Compliant device 18 is discussed more fully below. A template chuck 20 is coupled to orientation stage 10, shown more clearly in FIG. 2. Specifically, template chuck 20 is coupled to compliant device 18. Template chuck 20 is configured to support a template 22, shown in FIG. 1. An exemplary template chuck is disclosed in U.S. patent publication No. 2004/0090611 entitled “Chuck System for Modulating Shapes of Substrate,” assigned to the assignee of the present invention and is incorporated by reference herein.

Referring to FIGS. 1 and 2, inner frame 12 has a central throughway 24, and outer frame 14 has a central opening 26 in superimposition with central throughway 24. Flexure ring 16 has an annular shape, e.g. circular or elliptical and is coupled to inner frame 12 and outer frame 14 and lies outside of both central throughway 24 and central opening 26. Specifically, flexure ring 16 is coupled to inner frame 12 at regions 28, 30, and 32 and outer frame 14 at regions 34, 36, and 38. Region 34 is disposed between regions 28 and 30 and disposed equidistant therefrom; region 36 is disposed between regions 30 and 32 and disposed equidistant therefrom; and region 38 is disposed between regions 28 and 32 and disposed equidistant therefrom. In this manner, flexure ring 16 surrounds compliant device 18, template chuck 20, and template 22 and fixedly attaches inner frame 12 to outer frame 14.

Orientation stage 10 is configured to control movement of template 22 and place the same in a desired spatial relationship with respect to a reference surface (not shown). To that end, plurality of actuators 40, 42, and 44 are connected between outer frame 14 and inner frame 12 so as to be spaced about orientation stage 10. Each of actuators 40, 42, and 44 has a first end 46 and a second end 48. First end 46 of actuator 40 faces outer frame 14, and second end 48 faces inner frame 12. Actuators 40, 42, and 44 tilt inner frame 12 with respect to outer frame 14 by facilitating translational motion of inner frame 12 along three axes Z₁, Z₂, and Z₃. Orientation stage 10 may provide a range of motion of approximately ±1.2 mm about axes Z₁, Z₂, and Z₃. In this fashion, actuators 40, 42, and 44 cause inner frame 12 to impart angular motion to both compliant device 18 and, therefore, template 22 and template chuck 20, angular motion about one or more of a plurality of axes T₁, T₂ and T₃. Specifically, by decreasing a distance between inner frame 12 and outer frame 14 along axes Z₂ and Z₃ and increasing a distance therebetween along axis Z₁, angular motion about tilt axis T₂ occurs in a first direction. Increasing the distance between inner frame 12 and outer frame 14 along axes Z₂ and Z₃ and decreasing the distance therebetween along axis Z₁, angular motion about tilt axis T₂ occurs in a second direction opposite to the first direction. In a similar manner angular movement about axis T₁ may occur by varying the distance between inner frame 12 and outer frame 14 by movement of inner frame 12 along axes Z₁ and Z₂ in the same direction and magnitude while moving of the inner frame 12 along axis Z₃ in a direction opposite and twice to the movement along axes Z₁ and Z₂. Similarly, angular movement about axis T₃ may occur by varying the distance between inner frame 12 and outer frame 14 by movement of inner frame 12 along axes Z₁ and Z₃ in the same direction and magnitude while moving of inner frame 12 along axis Z₂ in direction opposite and twice to the movement along axes Z₁ and Z₃. Actuators 40, 42, and 44 may have a maximum operational force of ±200 N. Orientation stage 10 may have a may provide a range of motion of approximately ±0.15° about axes T₁, T₂, and T₃.

Actuators 40, 42, and 44 are selected to minimize mechanical parts and, therefore, minimize uneven mechanical compliance, as well as friction, which may cause particulates. Examples of actuators 40, 42, and 44 include voice coil actuators, piezo actuators, and linear actuators. An exemplary embodiment for actuators 40, 42, and 44 is available from BEI Technologies of Sylmar, Calif. under the trade name LA24-20-000A. Additionally, actuators 40, 42, and 44 are coupled between inner frame 12 and outer frame 14 so as to be symmetrical disposed thereabout and lie outside of central throughway 24 and central opening 26. With this configuration an unobstructed throughway between outer frame 14 to compliant device 18 is configured. Additionally, the symmetrical arrangement minimizes dynamic vibration and uneven thermal drift, thereby providing fine-motion correction of inner frame 12.

The combination of the inner frame 12, outer frame 14, flexure ring 16 and actuators 40, 42, and 44 provides angular motion of compliant device 18 and, therefore, template chuck 20 and template 22 about tilt axes T₁, T₂ and T₃. It is desired, however, that translational motion be imparted to template 22 along axes that lie in a plane extending transversely, if not orthogonally, to axes Z₁, Z₂, and Z₃. This is achieved by providing compliant device 18 with a functionality to impart angular motion upon template 22 about one or more of a plurality of compliance axes, shown as C₁ and C₂, which are spaced-part from tilt axes T₁, T₂ and T₃ and exist on the surface of the template when the template, the template chuck, and the compliant device are assembled.

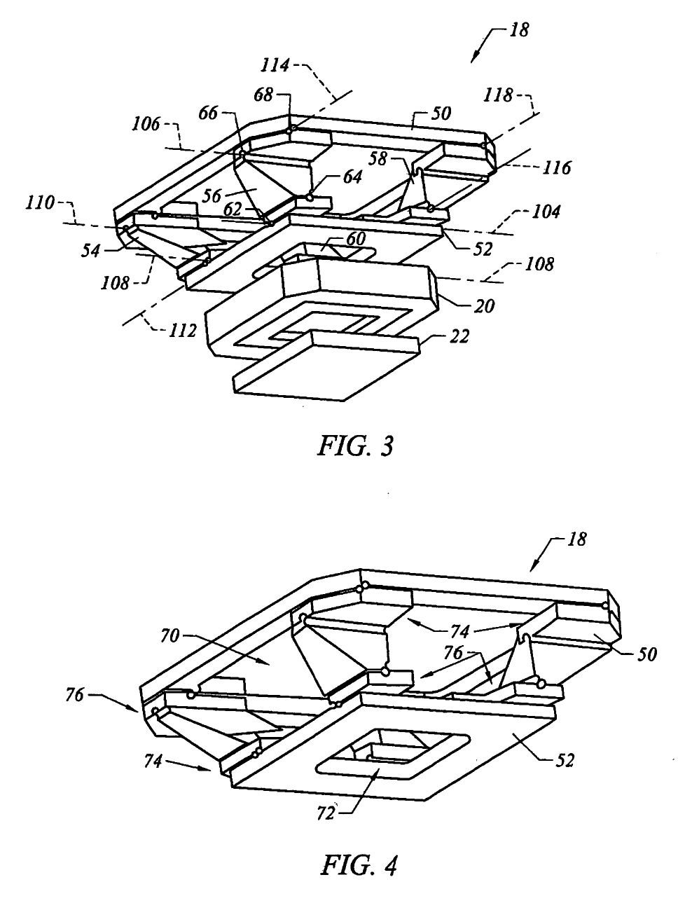

Referring to FIGS. 3 and 4, compliant device 18 includes a support body 50 and a floating body 52 that is coupled to the support body 50 vis-à-vis a plurality of flexure arms 54, 56, 58, and 60. Template chuck 20 is intended to be mounted to floating body 52 via conventional fastening means, and template 22 is retained by chuck using conventional methods.

Each of flexure arms 54, 56, 58, and 60 includes first and second sets of flexure joints 62, 64, 66, and 68. The first and second sets of flexure joints 62, 64, 66, and 68 are discussed with respect to flexure arm 56 for ease of discussion, but this discussion applies equally to the sets of flexure joints associated with flexure arms 56, 58, and 60. Although it is not necessary, compliant device 18 is formed from a solid body, for example, stainless steel. As a result, support body 50, floating body 52 and flexures arms 54, 56, 58, and 60 are integrally formed, are rotationally coupled together vis-à-vis first and second sets of flexure joints 62, 64, 66, and 68. Support body 50 includes a centrally disposed throughway 70. Floating body includes a centrally disposed aperture 72 that is in superimposition with throughway 70. Each flexure arm 54, 56, 58, and 60 includes opposed ends, 74 and 76. End 74 of each flexure arms 54, 56, 58, and 60 is connected to support body 50 through flexure joints 66 and 68. End 74 lies outside of throughway 70. End 76 of each flexure arm 54, 56, 58, and 60 is connected to floating body 52 through flexure joints 62 and 64. End 76 lies outside of aperture 72.

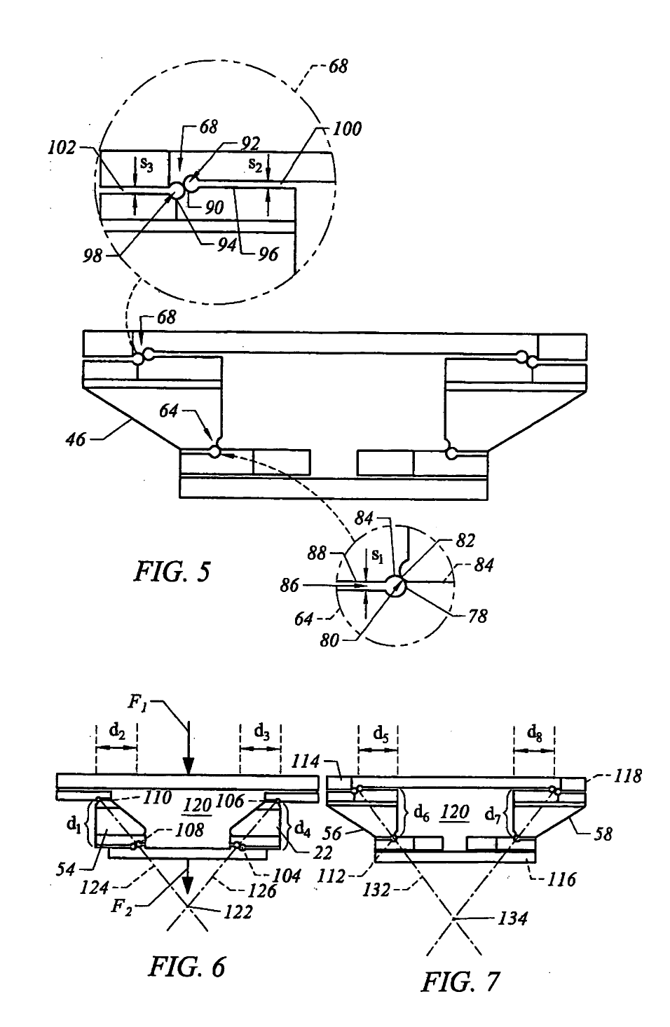

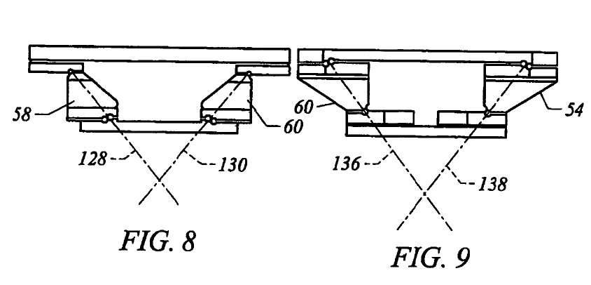

Referring to FIGS. 4 and 5, each of joints 62, 64, 66, and 68 are formed by reducing material from device 18 proximate to ends 74 and 76, i.e., at an interface either of support body 50 or floating body 52 and one of flexure arms 54, 56, 58, and 60. To that end, flexure joints 62, 64, 66, and 68 are formed by machining, laser cutting or other suitable processing of device 18. Specifically, joints 62, 64, 66, and 68 are formed from a flexure member 78 having two opposing surfaces 80 and 82. Each of surfaces 80 and 82 includes a hiatus 84 and 86. Hiatus 84 is positioned facing away from hiatus 86, and hiatus 86 faces away from hiatus 84. Extending from hiatus 86, away from surface 80 is a gap 88, terminating in an opening in a periphery of flexure arm 56. Joint 68 is also formed from a flexure member 90 having two opposing surfaces 92 and 94. Each of surfaces 92 and 94 includes a hiatus 96 and 98, respectively. Hiatus 98 is positioned facing surface 92, and hiatus 98 faces away from surface 94. Extending from hiatus 98, away from surface 92 is a gap 100, and extending from hiatus 98 is a gap 102. The spacing S1, S2 and S3 of gaps 88, 100, and 102, respectively define a range of motion over which relative movement between either of support body 50 and floating body 52 may occur.

Referring to FIGS. 3 and 5, flexure member 78 associated with joints 62 of flexure arms 56 and 58 facilitates rotation about axis 136, and flexure member 78 associated with joints 66 of flexure arms 56 and 58 facilitates rotation about axis 138. Flexure member 78 associated with joints 62 of flexure arms 54 and 60 facilitates rotation about axis 108, and flexure member 78 associated with joints 66 of flexure arms 54 and 60 facilitates rotation about axis 110. Flexure member 78 associated with joints 64 of flexure arms 54 and 56 facilitates rotation about axis 112, and flexure member 90 associated with joints 68 of flexure arms 54 and 56 facilitates rotation about axis 114. Flexure member 78 associated with joints 64 of flexure arms 58 and 60 facilitates rotation about axis 116, and flexure member 90 associated with joints 68 of flexure arms 58 and 60 facilitates rotation about axis 118.

As a result, each flexure arm 54, 56, 58, and 60 is located at a region of said device 18 where groups of the axes of rotation overlap. For example, end 74 of flexure arm 54 is located where axes 72 and 76 overlap and end 76 is positioned where axes 74 and 78 overlap. End 74 of flexure arm 56 is located where axes 68 and 76 overlap, and end 76 is positioned where axes 70 and 78 overlap. End 74 of flexure arm 58 is located where axes 68 and 80 overlap, and end 76 is located where axes 70 and 82 overlap. Similarly, end 74 of flexure arm 60 is located where axes 72 and 80 overlap, and end 76 is located where 82 and 74 overlap.

As a result of this configuration, each flexure arm 54, 56, 58, and 60 is coupled to provide relative rotational movement with respect to support body 50 and floating body 52 about two groups of overlapping axes with a first group extending transversely to the remaining group. This provides each of flexure arms 54, 56, 58, and 60 with movement about two groups of orthogonal axes while minimizing the footprint of the same. Device 18 may provide a tilting motion range of approximately ±0.04°, an active tilting motion range of approximately ±0.02°, and an active theta motion range of approximately ±0.0005° above the above mentioned axes. Furthermore, having the reduced footprint of each flexure arm 54, 56, 58, and 60 allows leaving a void 120 between throughway 70 and aperture 72 unobstructed by flexure arms 54, 56, 58, and 60. This makes device 18 suited for use with an imprint lithography system, discussed more fully below.

Referring to FIGS. 4, 6 and 7, the present configuration of flexure arms 54, 56, 58, and 60 with respect to support body 50 and floating body 52 facilitates parallel transfer of loads in device 18. For example, were a load force imparted upon support body 50, each flexures arms 54, 56, 58, and 60 imparts an substantially equal amount of force F₁ upon floating body 52. Among other things, this facilitates obtaining a desired structural stiffness with device 18 when load with either a force F₁ or a force F₂. To that end, joints are 62, 64, 66, and 68 are revolute joints which minimize movement, in all directions, between the flexure are and either support body 50 or floating body 52 excepting rotational movement. Specifically, joints 62, 64, 66, and 68 minimize translational movement between flexure arms 54, 56, 58, and 60, support body 50 and floating body 52, while facilitating rotational movement about axes 104, 106, 108, 110, 112, 114, 116, and 118.

Referring to FIGS. 4, 5, 6, and 7, the relative position of axes 104, 106, 108, and 110 provides floating body 52 with a first remote of compliance (RCC) at a position 122 spaced apart from floating body 52, centered with respect to aperture 72 and equidistant from each axis 104, 106, 108, and 110. Similarly, the relative position of axes 112, 114, 116, and 118 provides floating body 52 with a second RCC substantially close to position 122 and desirably located at position 122. Each axis 112, 114, 116, and 118 is positioned equidistant from position 122. Each axis of the group of axes 104, 106, 108, and 110 extends parallel to the remaining axes 104, 106, 108, and 110 of the group. Similarly, each axis of the group of axes 104, 106, 108, and 110 extends parallel to the remaining axes 104, 106, 108, and 110 of the group and orthogonally to each axis 104, 106, 108, and 110. Axis 110 is spaced-apart from axis 108 along a first direction a distance d₁and along a second orthogonal direction a distance d₂. Axis 104 is spaced-apart from axis 106 along the first direction a distance d₃ and along the second direction a distance d₄. Axis 112 is spaced-apart from axis 114 along a third direction, that is orthogonal to both the first and second directions a distance d₅ and along the second direction a distance d₆. Axis 116 is spaced-apart from axis 118 along the second direction a distance d7 and along the third direction a distance d₈. Distances d₁, d₄, d₆ and d₇ are substantially equal. Distances d₂, d₃, d₅ and d₈ are substantially equal.

Two sets of transversely extending axes may be in substantially close proximity such that RCC 122 may be considered to lie upon an intersection thereat by appropriately establishing distances d₁-d₈. A first set of includes four axes is shown as 124, 126, 128, and 130. Joints 62 and 66 of flexure arm 54 lie along axis 124, and joints 62 and 66 of flexure arm 54 lie along axis 126. Joints 62 and 66 of flexure arm 58 lie along axis 128, and joints 62 and 66 of flexure arm 60 lie along axis 130. A second set of four axes is shown as 132, 134, 136, and 138. Joints 64 and 68 of flexure arm 56 lie along axis 132, and joints 64 and 68 of flexure arm 58 lie along axis 134. Joints 64 and 68 of flexure arm 60 lie along axis 136, and joints 64 and 68 of flexure arm 54 lie along axis 138. With this configuration movement of floating body 52, with respect to RCC 122, about any one of the set of axes 124, 126, 128, 130, 132, 134, 136, and 138 is decoupled from movement about the remaining axes 124, 126, 128, 130, 132, 134, 136, and 138. This provides a gimbal-like movement of floating body 52 with respect to RCC 122. With the structural stiffness to resist, if not prevent, translational movement of floating body with respect to axis 124, 126, 128, 130, 132, 134, 136, and 138.

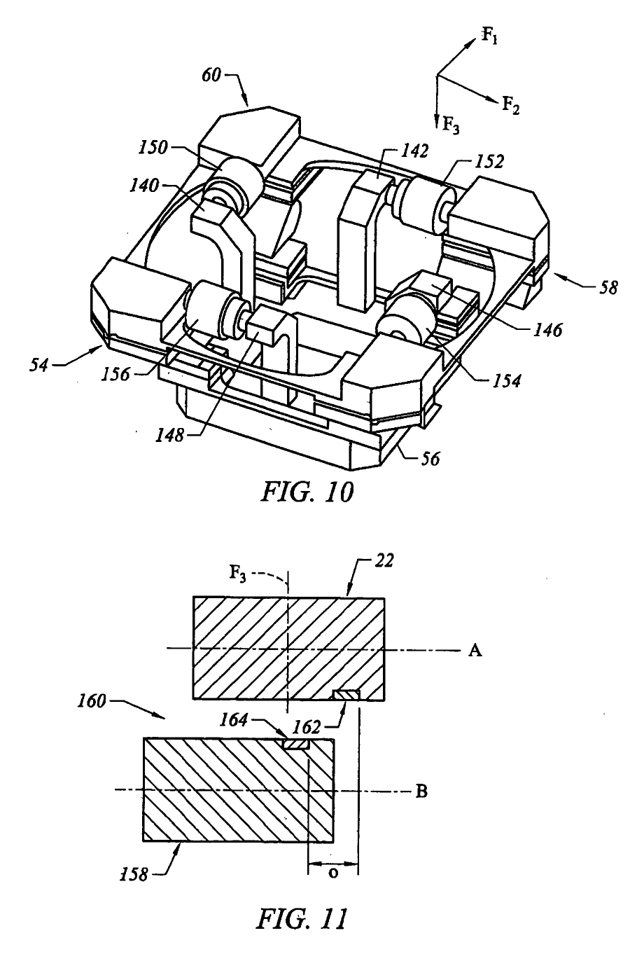

Referring to FIGS. 4 and 10, in accordance with an alternate embodiment of the present invention, device 18 may be provided with active compliance functionality shown with device 18. To that end, a plurality of lever arms 140, 142, 146, and 148 are coupled to floating body 52 and extend toward support body 50 terminating proximate to a piston of an actuator. As shown lever arm 140 has one end positioned proximate to the piston of actuator 150, lever arm 142 has one end positioned proximate to the piston of actuator 152, lever arm 146 has one end positioned proximate to the piston of actuator 154 and one end of actuator arm 118 is positioned proximate to the piston of actuator 156 that is coupled thereto. By activating the proper sets of actuators 150, 152, 154, and 156, angular positioning of the relative position of floating body 52 with respect to support body 50 may be achieved. An exemplary embodiment for actuators 150, 152, 154, and 156 is available from BEI Technologies of Sylmar, Calif. under the trade name LA10-12-027A.

To provide rotational movement of floating body 52 with respect to support body 50 actuators 150, 152, 154, and 156 may be activated. For example, actuator 150 may be activated to move lever arm 140 along the F₁ direction and actuator 154 would be operated to move lever arm 146 in a direction opposite to the direction lever arm 140 moves. Similarly, at least one of actuators 152 and 156 are activated to move lever arms 142 and 148 respectively. Assuming both actuators 152 and 156 are activated, then each of lever arms 140, 142, 146, and 148 are moved toward one of flexure arms 54, 56, 58, and 60 that differs from the flexure arm 54, 56, 58, and 60 toward which the remaining lever arms 140, 142, 146, and 148 move. An example may include moving lever arm 140 toward flexure arm 54, lever arm 142 toward flexure arm 56, lever arm 146 toward flexure arm 58 and lever arm 142 toward flexure arm 60. This would impart rotational movement about the F₃ direction. It should be understood, however, each of lever arms 140, 142, 146, and 148 may be moved in the opposite direction. Were it desired to prevent translational displacement between support body 50 and floating body 52 along the F₃ direction while imparting rotational movement thereabout, then each of lever arms 140, 142, 146, and 148 would be moved the same magnitude. However, were it desired to impart rotational movement of floating body 52 about the F₁ and F₂ directions, this may be achieved in various manners.

Since rotational movement of floating body 52 is guided by the first and second RCCs, floating body 52 can be actively adjusted for two independent angular configuration with respect to support body by translation along the F₃ direction. For example, moving each of lever arms 140, 142, 146, and 148 with actuators 150, 152, 154, and 156, respectively, differing amounts would impart translation of floating body 52 along the F₃ direction while imparting angular displacement about the F₃ direction. Additionally, moving only three lever arms 140, 142, 146, and 148 would also impart translation motion about the F₃ direction while imparting angular displacement about the F₃ direction. Were it desired to provide impart translational motion between support body 50 and floating body 52 without impart rotational movement therebetween, two of actuators 150, 152, 154, and 156 would be activated to move two of lever arms 140, 142, 146, and 148. In one example, two opposing lever arms, such as for example, 140 and 146, or 142 and 148 would be moved in the same direction the same magnitude. Moving lever arms 140 and 146 in one direction, e.g., toward flexure arms 60 and 58, respectively, would cause the entire side of floating body 52 extending between flexure arms 58 and 60 to increase in distance from the side of support body 50 in superimposition therewith, effectively creating rotation movement of floating body 16 about the F₂ direction. Decrease would the distance between the side of floating body 52 extending between flexure arms 56 and 54 and the side of support body 50 in superimposition therewith. Conversely, moving lever arms 140 and 146 in an opposite direction, e.g., toward flexure arms 54 and 56, would cause the entire side of floating body 52 extending between flexure arms 58 and 60 to decrease in distance from the side of support body 50. The distance between the side of floating body 52 extending between flexure arms 58 and 60 and the side of support body 50 in superimposition therewith would increase. Similarly, rotational movement of floating body 52 about the F₁ direction may be achieved by movement of lever arms 142 and 148 with actuators 152 and 156, respectively, as discussed above with respect to movement of lever arms 140 and 146. It should be understood that any linear combination of movement of the aforementioned lever arms may be effectuated to achieve desired motion.

From the foregoing it is seen that rotational motions of floating body 52 about the F₁, F₂ and F₃ directions are orthogonal to each other. By adjusting the magnitude of each actuation force or position at actuators 150, 152, 154 and 156, any combination or rotational motions about the F₁, F₂ and F₃ directions are constrained by the structural stiffness of flexure arms 54, 56, 58, and 60, floating body 52 and support body 50.

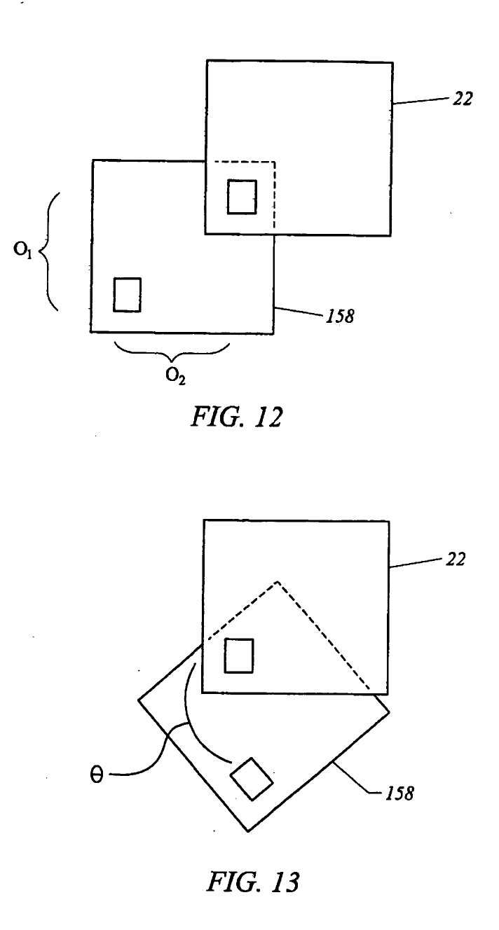

Referring to FIGS. 1, 11 and 12, in operation, orientation stage 10 is typically employed with an imprint lithography system (not shown). An exemplary lithographic system is available under the trade name IMPRIO 100™ from Molecular Imprints, Inc. having a place of business at 1807-C Braker Lane, Suite 100, Austin, Tex. 78758. The system description for the IMPRIO 100TM is available at www.molecularimprints.com and is incorporated herein by reference. As a result, orientation stage 10 may be employed to facilitate alignment of template 22 with a surface in superimposition therewith, such as a surface of substrate 158. As a result, the surface of substrate 158 may comprising of the material from which substrate 158 is formed, e.g. silicon with a native oxide present, or may consist of a patterned or unpatterned layer of, for example, conductive material, dielectric material and the like.

Template 22 and substrate 158 are shown spaced-apart a distance defining a gap 160 therebetween. The volume associated with gap 160 is dependent upon many factors, including the topography of the surface of template 22 facing substrate and the surface of substrate 158 facing template 22, as well as the angular relationship between a neutral axis A of substrate with respect to the neutral axis B of substrate 158. In addition, were the topography of both of the aforementioned surfaces patterned, the volume associated with gap 160 would also be dependent upon the angular relation between template 22 and substrate 158 about axis Z. Considering that desirable patterning with imprint lithography techniques is, in large part, dependent upon providing the appropriate volume to gap 160, it is desirable to accurate align template 22 and substrate 158. To that end, template 22 includes template alignment marks, one of which is shown as 162, and substrate 158 includes substrate alignment marks, one of which is shown as 164.

In the present example it is assumed that desired alignment between template 22 and substrate 158 occurs upon template alignment mark 162 being in superimposition with substrate alignment mark 164. As shown, desired alignment between template 22 and substrate 158 has not occurred, shown by the two marks be offset, a distance O. Further, although offset O is shown as being a linear offset in one direction, it should be understood that the offset may be linear along two direction shown as O1 and O2. In addition to, or instead of, the aforementioned linear offset in one or two directions, the offset between template 22 and substrate 158 may also consist of an angular offset, shown in FIG. 13 as angle Θ.

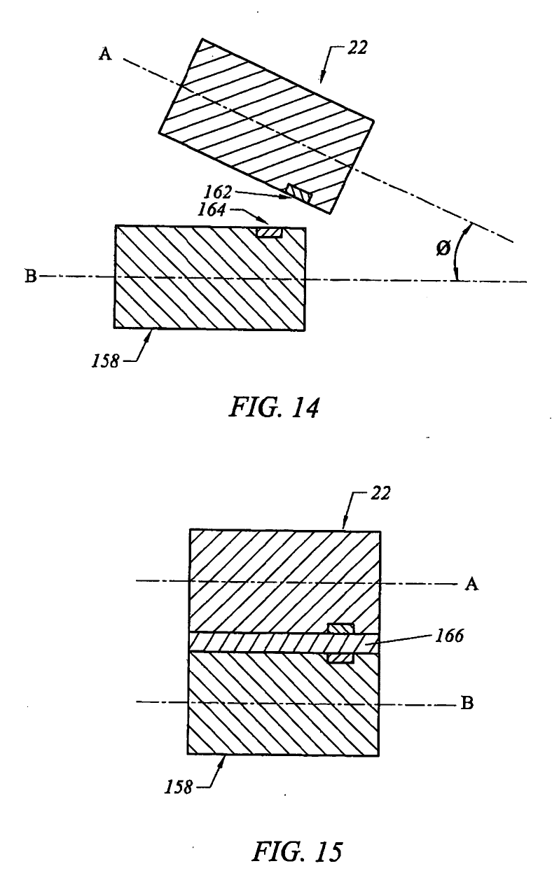

Referring to FIGS. 2, 10, and 14, desired alignment between template 22 and substrate 158 is obtained by the combined rotational movement about one or more axes T₁, T₂, T₃, F₁, F₂ and F₃. Specifically, to attenuate offset linear offset, movement, as a unit, of compliant device 18, template chuck 20 and template 22 about one or more axes T₁, T₂, T₃ is undertaken. This typically results in an oblique angle φ being produced between neutral axes A and B. Thereafter, angular movement of template 22 about one or more of axes F₁ and F₂ are undertaken to compensate for the angle φ and ensure that neutral axis A extends parallel to neutral axis B. Furthermore, the combined angular movement about axes T₁, T₂, T₃, F₁, F₂ results in a swinging motion of template 22 to effectuate movement of the same in a plane extending parallel to neutral axis B and transverse, of not orthogonal, to axes Z₁, Z₂ and Z₃. In this manner, template 22 may be properly aligned with respect to substrate 158 along to linear axes lying in a plane extending parallel to neutral axis B, shown in FIG. 15. Were it desired to attenuate, of not abrogate, angular offset, template 22 would be rotated about axis F3 by use of actuators 150, 152, 154, and 156 to provide the desired alignment.

After the desired alignment has occurred, actuators 40, 42, and 44 are operated to move template 22 into contact with a surface proximate to substrate. In the present example surface consists of polymerizable imprinting material 166 disposed on substrate 158. It should be noted that actuators 40, 42, and 44 are operated to minimize changes in the angle formed between neutral axes A and B once desired alignment has been obtained. It should be known, however, that it is not necessary for neutral axes A and B to extend exactly parallel to one another, so long as the angular deviation from parallelism is within the compliance tolerance of compliant device 18, as defined by flexure joints 62, 64, 66, and 68 and flexure arms 54, 56, 58, and 60. In this fashion, neutral axes A and B may be orientated to be as parallel as possible in order to maximize the resolution of pattern formation into polymerizable material. As a result, it is desired that position 122 at which the first and second RCCs are situation be placed at the interface of template 22 and material.

Referring to FIGS. 1, 16 and 17, as discussed above, the foregoing system 10 is useful for patterning substrates, such as substrate 158 employing imprint lithography techniques. To that end, template 22 typically includes a mesa 170 having a pattern recorded in a surface thereof, defining a mold 172. An exemplary template 22 is shown in U.S. Pat. No. 6,696,220, which is incorporated by reference herein. The patterned on mold 172 may comprising of a smooth surface of a plurality of features, as shown, formed by a plurality of spaced-apart recesses 174 and projections 176. Projections 30 have a width W₁, and recesses 28 have a width W₂. The plurality of features defines an original pattern that forms the basis of a pattern to be transferred into a substrate 158.

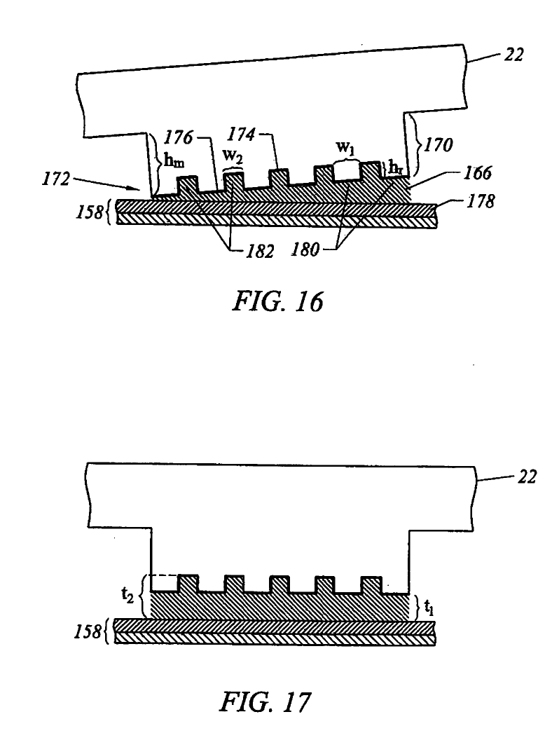

Referring to FIGS. 16 and 17 the pattern recorded in material 166 is produced, in part, by mechanical contact of the material 166 with mold 172 and substrate 158, which as shown, may include an existing layer thereon, such as a transfer layer 178. An exemplary embodiment for transfer layer 178 is available from Brewer Science, Inc. of Rolla, Mo. under the trade name DUV30J-6. It should be understood that material 166 and transfer layer 178 may be deposited using any known technique, including drop dispense and spin-coating techniques.

Upon contact with material 166, it is desired that portion 180 of material 166 in superimposition with projections 30 remain having a thickness t₁, and sub-portions 182 remain having a thickness t₂. Thickness t₁ is referred to as a residual thickness. Thicknesses “t₁” and “t₂” may be any thickness desired, dependent upon the application. Thickness t₁ and t₂ may have a value in the range of 10 nm to 10 μm. The total volume contained material 166 may be such so as to minimize, or to avoid, a quantity of material 166 from extending beyond the region of substrate 158 not in superimposition with mold 172, while obtaining desired thicknesses t₁ and t₂. To that end, mesa 170 is provided with a height, hₘ, which is substantially greater than a depth of recesses 174, hᵣ. In this manner, capillary forces of material 166 with substrate 158 and mold 172 restrict movement of material 166 from extending beyond regions of substrate 158 not in superimposition with mold 172, upon t₁ and t₂ reaching a desired thickness.

A benefit provided by system 10 is that it facilitates precise control over thicknesses t₁ and t₂. Specifically, it is desired to have each of thicknesses t₁ be substantially equal and that each of thicknesses t₂ be substantially equal. As shown in FIG. 16, thicknesses t₁ are not uniform, as neither are thickness t₂. This is an undesirable orientation of mold 172 with respect to substrate 158. With the present system 10, uniform thickness t₁ and t₂ may be obtained, shown in FIG. 17. As a result, precise control over thickness t₁ and t₂ may be obtained, which is highly desirable. In the present invention, system 10 provide a three sigma alignment accuracy having a minimum feature size of, for example, about 50 nm or less.

The embodiments of the present invention described above are exemplary. As a result, many changes and modifications may be made to the disclosure recited above, while remaining within the scope of the invention. Therefore, the scope of the invention should not be limited by the above description, but instead should be determined with reference to the appended claims along with their full scope of equivalents.

1. A compliant device, comprising:
a support body;
a floating body; and
a plurality of flexure arms, each of which is connected between said support body and said floating body to transfer a load between said support body in parallel with the remaining flexure arms of said plurality of flexure arms.

2. The compliant device as recited in claim 1 wherein a subset of said plurality of flexure arms each has a first set and a second set of flexure joints, with said first set of flexure joints facilitating rotational movement of said flexure arm about a first axis and said second set of flexure joints arranged to facilitate rotational movement of said flexure arm about a second axis.

3. The device as recited in claim 1 wherein said plurality of flexure members are coupled between said support body and said floating body to facilitate relative rotational movement between said floating body and said support body about two transversely extending axes intersecting at a point.

4. The device as recited in claim 1 wherein said plurality of flexure members are coupled between said support body and said floating body to facilitate relative rotational movement between said floating body and said support body about two transversely extending axes intersecting at a point, with movement of about one of said two transversely extending axes being decoupled from movement about the remaining of axis of said two transversely extending axes.

5. The device as recited in claim 1 wherein said plurality of flexure members are coupled between said support body and said floating body to facilitate relative rotational movement between said floating body and said support body about two transversely extending axes intersecting at a point, while minimizing relative translation movement between said support body and said floating body.

6. The compliant device as recited in claim 1 wherein a subset of said plurality of flexure arms each has two sets of revolute joints arranged to facilitate rotational movement of said flexure arm about two transverse axes.

7. The compliant device as recited in claim 1 wherein said support body, said floating body and said plurality of flexure arms are integrally formed.

8. The compliant device as recited in claim 1 wherein said plurality of flexure arms are coupled so that all loads transferred between said support body and said floating body occurs in parallel.

9. The compliant device as recited in claim 1 wherein said floating body includes an aperture with one end of each of said plurality of flexure arms being coupled to said floating body, outside of said aperture.

10. The compliant device as recited in claim 1 wherein said support body includes a throughway, with a second end of said plurality of flexure arms being coupled to said support body outside of said throughway.

11. The compliant device as recited in claim 1 further including an actuator system coupled to facilitate angular and translational movement between said support body and said floating body.

12. A compliant device, comprising:
a support body;
a floating body; and
a plurality of flexure arms each of which being coupled to allow rotational movement between said support body and said floating body about a first axis group and a second axis group, with said first axis group extending transversely to said second axis group.

13. The compliant device as recited in claim 12 wherein said plurality of flexure arms consists of four flexure arms coupled between said floating body and said support body to facilitate rotational movement about a point while minimizing translational movement along a predetermined set of axes.

14. The compliant device as recited in claim 12 wherein said plurality of flexure arms are coupled between said floating body and said support body to facilitate rotational movement about a point spaced-apart from both said support body and said floating body, while minimizing translation movement of said floating body along predetermined axes.

15. The device as recited in claim 12 wherein said plurality of flexure members are coupled between said support body and said floating body to facilitate relative rotational movement between said floating body and said support body about two transversely extending axes intersecting at a point.

16. The device as recited in claim 12 wherein said plurality of flexure members are coupled between said support body and said floating body to facilitate relative rotational movement between said floating body and said support body about two transversely extending axes intersecting at a point, with movement of about one of said two transversely extending axes being decoupled from movement about the remaining of axis of said two transversely extending axes.

17. The device as recited in claim 12 wherein said plurality of flexure members are coupled between said support body and said floating body to facilitate relative rotational movement between said floating body and said support body about two transversely extending axes intersecting at a point, while minimizing relative translation movement between said support body and said floating body.

18. The compliant device as recited in claim 12 wherein a subset of said plurality of flexure arms each has a group of flexure joints, one of which is coupled to facilitate rotation about a first axis, with the remaining flexure joint coupled to facilitate rotational movement about a second axis extending transversely to said first axis.

19. The compliant device as recited in claim 12 wherein a subset of said plurality of flexure arms each has two sets of revolute joints arranged to facilitate rotational movement of said flexure arm about two transverse axes.

20. The compliant device as recited in claim 12 wherein said support body, said floating body and said plurality of flexure arms are integrally formed.

21. The compliant device as recited in claim 12 wherein said plurality of flexure arms are coupled so that all loads transferred between said support body and said floating body occurs in parallel.

22. The compliant device as recited in claim 12 further including an actuator system coupled to facilitate angular and translational movement between said support body and said floating body.

22. The compliant device as recited in claim 12 wherein said floating body includes an aperture and said support body includes a throughway in superimposition with said aperture, with a first end of each of said flexure arms being coupled to said floating body, outside of said aperture and a second end of each of said plurality of flexure arms being coupled to said support body outside of said throughway.

23. A compliant device, comprising:
a support body;
a floating body; and
a plurality of flexure arms coupled between said support body and said floating body to allow rotational movement between said support body and said floating body about a plurality of axes, with each of said plurality of flexures arms being positioned at a place where a group of said plurality of axes overlap.

24. The compliant device as recited in claim 23 wherein a first end of each of said plurality of flexure arms is coupled to said support body where a first pair of said plurality of axes overlap, and a second end of each of said plurality of flexure arms are coupled to said floating body where a second pair of said plurality of axes overlap.

25. The compliant device as recited in claim 23 wherein a subset of said plurality of flexure arms each has a first set and a second set of flexure joints, with said first set of flexure joints facilitating rotational movement about a first group of axes extending along a first direction and said second set of flexure joints facilitating rotational movement of said flexure arm about a second group of axes extending along a second direction, transversely to said first direction.

26. The device as recited in claim 23 wherein said plurality of flexure members are coupled between said support body and said floating body to facilitate relative rotational movement between said floating body and said support body about two transversely extending axes intersecting at a point.

27. The device as recited in claim 23 wherein said plurality of flexure members are coupled between said support body and said floating body to facilitate relative rotational movement between said floating body and said support body about two transversely extending axes intersecting at a point, with movement of about one of said two transversely extending axes being decoupled from movement about the remaining of axis of said two transversely extending axes.

28. The device as recited in claim 23 wherein said plurality of flexure members are coupled between said support body and said floating body to facilitate relative rotational movement between said floating body and said support body about two transversely extending axes intersecting at a point, while minimizing relative translational movement between said support body and said floating body.

29. The compliant device as recited in claim 23 wherein a subset of said plurality of flexure arms each has two sets of revolute joints arranged to facilitate rotational movement of said flexure arm about two transverse axes.

30. The compliant device as recited in claim 23 wherein said support body, said floating body and said plurality of flexure arms are integrally formed.

31. The compliant device as recited in claim 23 wherein said plurality of flexure arms are coupled so that all loads transferred between said support body and said floating body occurs in parallel.

32. The compliant device as recited in claim 23 wherein said floating body includes an aperture with one end of each of said flexure arms being coupled to said floating body, outside of said aperture.

33. The compliant device as recited in claim 23 wherein said floating body includes an aperture and said support body includes a throughway in superimposition with said aperture, with a first end of each of said flexure arms being coupled to said floating body, outside of said aperture and a second end of each of said plurality of flexure arms being coupled to said support body outside of said throughway.

34. The compliant device as recited in claim 23 further including an actuator system coupled to facilitate angular and translational movement between said support body and said floating body.
